(19) United States
(12) Patent Application Publication
(10) Pub. No.: US 2025/0203885 A1
(43) Pub. Date: Jun. 19, 2025

(54) MULTI-LAYER THIN FILM RESISTOR

(71) Applicant: Taiwan Semiconductor Manufacturing Company, Ltd., Hsinchu (TW)

(72) Inventors: Chung-Liang CHENG, Changhua City (TW); Guanyu LUO, Chiayi County (TW); Sheng-Chau CHEN, Kaohsiung (TW)

(21) Appl. No.: 18/403,280

(22) Filed: Jan. 3, 2024

Related U.S. Application Data
(60) Provisional application No. 63/612,238, filed on Dec. 19, 2023.

(51) Int. Cl. H10D 1/47

(52) U.S. Cl. CPC H10D 1/47

(57) ABSTRACT

Some implementations described herein provide a semiconductor device including a resistor structure. The resistor structure (e.g., a thin film resistor structure) includes a multi-layer film structure connecting contact structures of the resistor structure below the contact structures. The multi-layer film structure includes a capping layer, an upper resistive layer having a first concentration of silicon, and a lower resistive layer having a second concentration of silicon that is lesser relative to the first concentration. The multi-layer film structure may be subject to a lesser risk of oxidation relative to a single layer film structure that does not include the capping layer. Additionally, or alternatively, the combination of the upper and lower resistive layers (e.g., including the first and second concentrations of silicon) may allow for tuning of a mean resistive property and/or a temperature coefficient of resistance across the multi-layer film structure.

### CROSS-REFERENCE TO RELATED APPLICATION

This patent application claims priority to Provisional Patent Application No. 63/612,238, filed on Dec. 19, 2023, and entitled “MULTI-LAYER THIN FILM RESISTOR.” The disclosure of the prior application is considered part of and is incorporated by reference into this patent application.

### BACKGROUND

Semiconductor-based integrated circuits may include a wide range of semiconductor devices. These semiconductor devices may include active semiconductor devices and/or passive semiconductor devices. Active semiconductor devices may include transistors and other semiconductor devices that operate using a power source. Passive semiconductor devices include inductors, capacitors, resistors, and/or other semiconductor devices that can operate without a power source. Resistors are widely used in many applications, such as resistor-capacitor (RC) circuits, power drivers, power amplifiers, and/or radio frequency (RF) applications, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example semiconductor device described herein.

FIGS. 3A-3C are diagrams of an example implementation related to forming a multi-layer film structure described herein.

FIGS. 4A-4J are diagrams of an example implementation related to forming a semiconductor device including a multi-layer film structure described herein.

FIG. 5 is a diagram of example components of a device described herein.

FIG. 6 is a flowchart of an example process associated with forming a multi-layer film structure included as part of a resistor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor device includes a resistor structure (e.g., a thin film resistor structure). The resistor structure may include a single layer film structure, such as a single layer of a silicon chromium (SiCr) composition. A resistive property may vary throughout the single layer film structure to introduce variations to one or more performance characteristics, such as a variation in a voltage within the semiconductor device, an electrical current within the semiconductor device, and/or a variation in a temperature sensitivity of the resistor structure. Such variations may lead to a performance degradation within the semiconductor device (e.g., a degradation in a transient response that causes stability issues within the semiconductor device).

Some implementations described herein provide a semiconductor device including a resistor structure. The resistor structure (e.g., a thin film resistor structure) includes a multi-layer film structure connecting contact structures of the resistor structure below the contact structures. The multi-layer film structure includes a capping layer, an upper resistive layer having a first concentration of silicon, and a lower resistive layer having a second concentration of silicon that is lesser relative to the first concentration. The multi-layer film structure is subject to a lesser risk of oxidation relative to a single layer film structure that does not include the capping layer. Additionally, or alternatively, the combination of the upper and lower resistive layers (e.g., including the first and second concentrations of silicon) allows for tuning of a mean resistive property and/or a temperature coefficient of resistance across the multi-layer film structure to reduce a variation in a performance of the semiconductor device relative to another semiconductor device including another resistor structure using a single layer film structure.

In this way, a performance of the resistor structure including the multi-layer film structure is increased to satisfy a performance threshold. Additionally, or alternatively and based on a population of semiconductor devices including the resistor structure achieving an increased testing yield to the performance threshold, an amount of resources (e.g., labor, raw materials, semiconductor processing tools, and/or computing resources) required to fabricate the population of semiconductor devices is decreased.

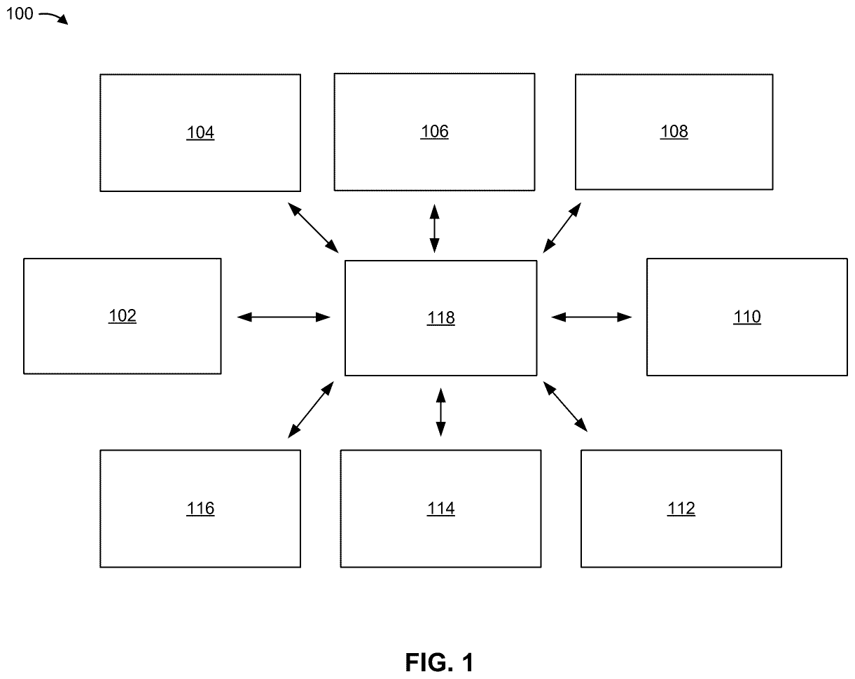

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, an ion implantation tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a CMP tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The ion implantation tool 116 is a semiconductor processing tool that is used to implant ions into a substrate such as a semiconductor wafer. The ion implantation tool 116 generates ions in an arc chamber from a source material such as a gas or a solid. The source material is provided into the arc chamber, and an arc voltage is discharged between a cathode and an electrode to produce a plasma containing ions of the source material. One or more extraction electrodes are used to extract the ions from the plasma in the arc chamber and accelerate the ions to form an ion beam. The ion beam may be directed toward the substrate such that the ions are implanted below the surface of the substrate to dope the substrate.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

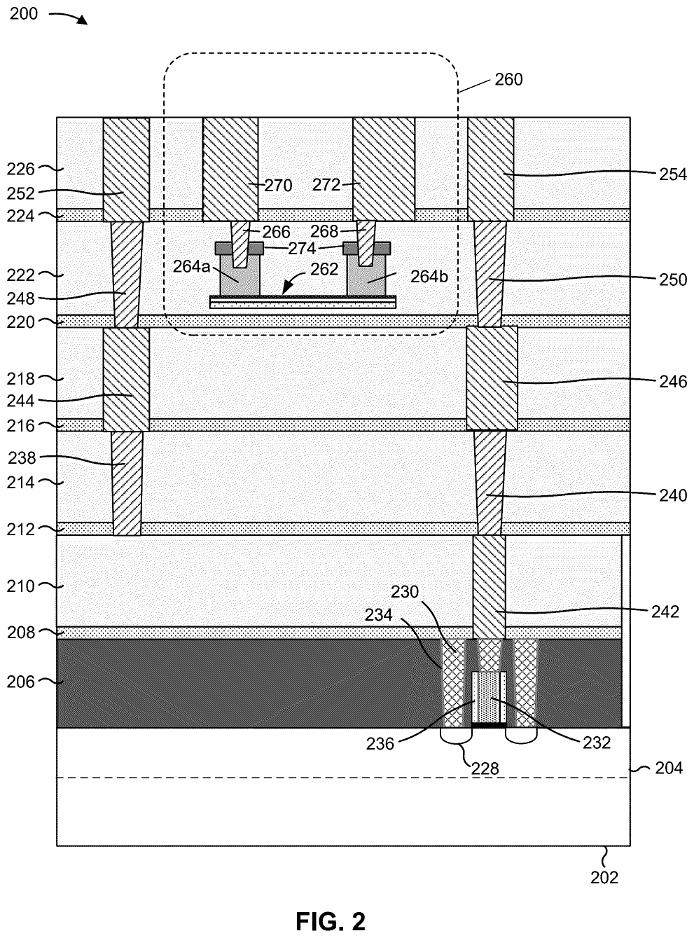

As described in greater detail in connection with FIGS. 2-7 and elsewhere herein, the semiconductor processing tools 102-116 may perform a series of operations. The series of operations includes forming a lower resistive layer, of a multi-layer film structure, that includes a first concentration of silicon over a dielectric layer. The series of operations includes forming an upper resistive layer, of the multi-layer film structure, that includes a second concentration of silicon over the lower resistive layer, where the second concentration of silicon is different than the first concentration of silicon. The series of operations includes forming a capping layer, of the multi-layer film structure, over the upper resistive layer.

The number and arrangement of tools shown in FIG. 1 are provided as one or more examples. In practice, there may be additional tools, fewer tools, different, or differently arranged tools than those shown in FIG. 1. Furthermore, two or more tools shown in FIG. 1 may be implemented within a single tool or a single tool shown in FIG. 1 may be implemented as multiple, distributed tools. Additionally, or alternatively, a set of tools (e.g., one or more tools) of the example environment 100 may perform one or more functions described as being performed by another set of tools of the example environment 100.

FIG. 2 is a diagram of a portion of an example semiconductor device 200 described herein. The semiconductor device 200 includes an example of a semiconductor device, such as a semiconductor memory device (e.g., a static random access memory (SRAM), a dynamic random access memory (DRAM)), a semiconductor logic device, a processor, an input/output device, or another type of semiconductor device that includes one or more transistors.

The semiconductor device 200 includes a substrate 202 (e.g., a silicon substrate) and one or more fin structures 204. The semiconductor device 200 further includes one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, 224 includes a layer of material that is configured to permit various portions of the semiconductor device 200 (or the layers included therein) to be selectively etched or protected from etching to form one or more of the structures included in the semiconductor device 200.

As further shown in FIG. 2, the semiconductor device 200 includes a plurality of epitaxial (epi) regions 228 that are grown and/or otherwise formed on and/or around portions of the fin structure 204. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation.

The epitaxial regions 228 function as source/drain regions of transistors included in the semiconductor device 200. In such cases, the source/drain region(s) may refer to a source or a drain, individually or collectively, dependent upon the context.

The epitaxial regions 228 are electrically connected to metal source or drain contacts 230 of the transistors included in the semiconductor device 200. The metal source or drain contacts 230 include cobalt (Co), ruthenium (Ru), and/or another conductive or metal material. The transistors further include gates 232, which are formed of a polysilicon material, a metal (e.g., tungsten (W) or another metal), and/or another type of conductive material. The metal source or drain contacts 230 and the gates 232 are electrically isolated by one or more sidewall spacers, including spacers 234 in each side of the metal source or drain contacts 230 and spacers 236 on each side of the gate 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the metal source or drain contacts 230.

As further shown in FIG. 2, the metal source or drain contacts 230 and the gates 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to a back end of line (BEOL) region of the semiconductor device 200.

The metal source or drain contacts 230 are electrically connected to interconnects 238 (e.g., source/drain vias). One or more of the gates 232 are electrically connected to interconnects 240 (e.g., gate vias). The interconnects 238 and 240 include a conductive material such as tungsten, cobalt, ruthenium, copper, and/or another type of conductive material. In some implementations, the gates 232 are electrically connected to the interconnects 240 by gate contacts 242 (CB or MP) to reduce contact resistance between the gates 232 and the interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of conductive layers, each including one or more metallization layers and/or vias. As an example, the interconnects 238 and 240 may be electrically connected to an M0 metallization layer that includes conductive structures 244 and 246. The M0 metallization layer is electrically connected to a V0 via layer that includes interconnects 248 and 250. The V0 via layer is electrically connected to an M1 metallization that includes conductive structures 252 and 254. In some implementations, the conductive layers of the semiconductor device 200 includes additional metallization layers and/or vias that connect the semiconductor device 200 to a package. The BEOL region of the semiconductor device 200 may refer to the region of the semiconductor device 200 above the ESL 208, including the structures/layers 210-226 and 238-254.

As further shown in FIG. 2, the semiconductor device 200 may include one or more devices and/or structures in the BEOL region of the semiconductor device 200. For example, the semiconductor device 200 may include one or more semiconductor resistor structures 260 in the BEOL region of the semiconductor device 200. The semiconductor resistor structure 260 may be included in one or more of the dielectric layers 210, 214, 218, 222, and/or 226 in the BEOL region of the semiconductor device 200. Accordingly, the semiconductor resistor structure 260 may be referred to as a resistor structure or a thin-film resistor (TFR) structure, among other examples.

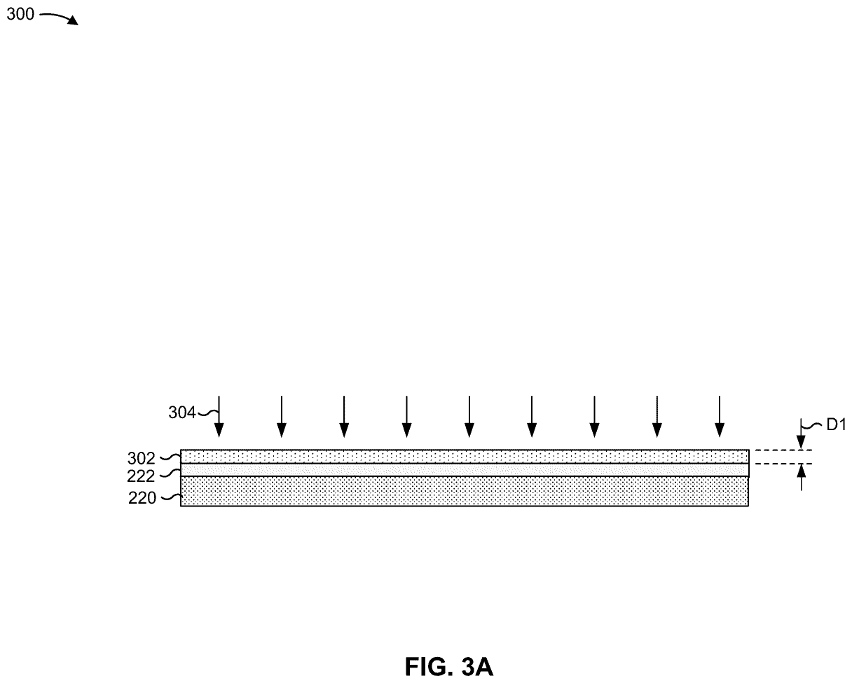

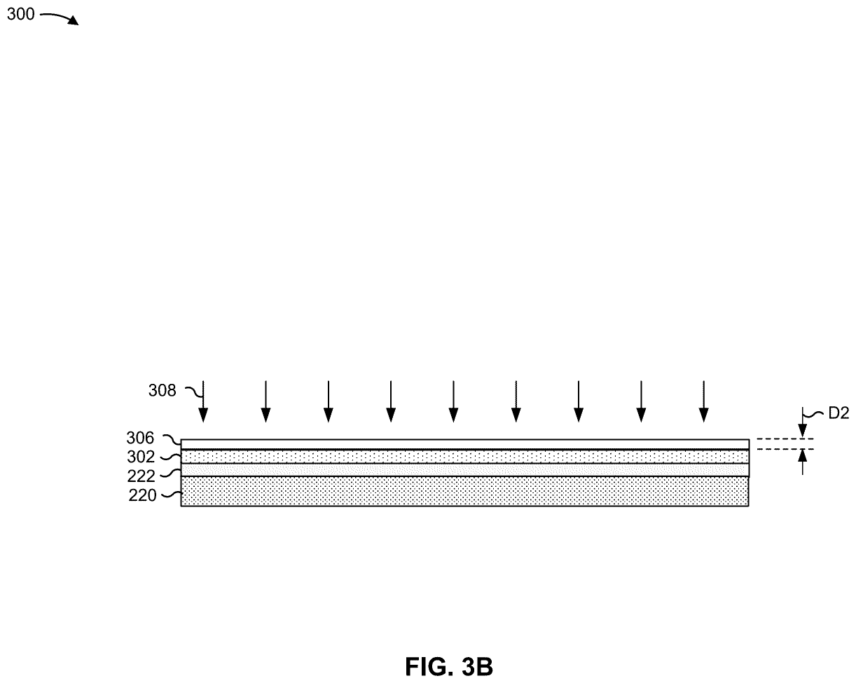

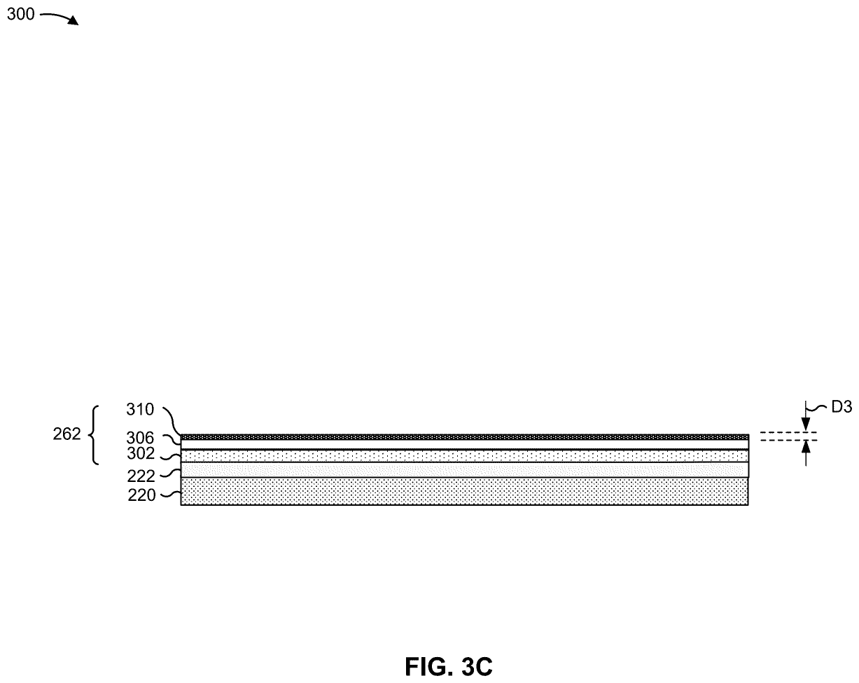

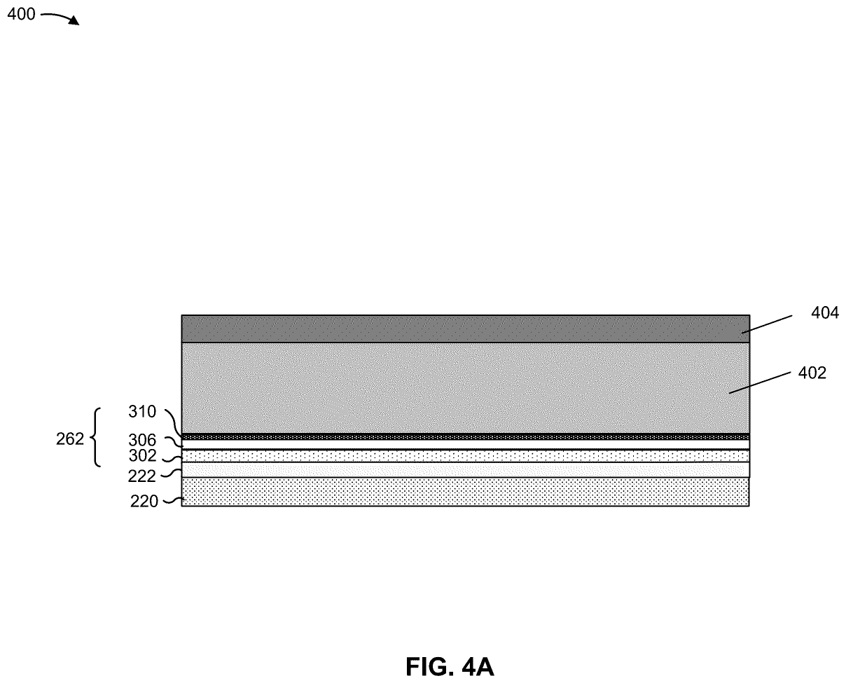

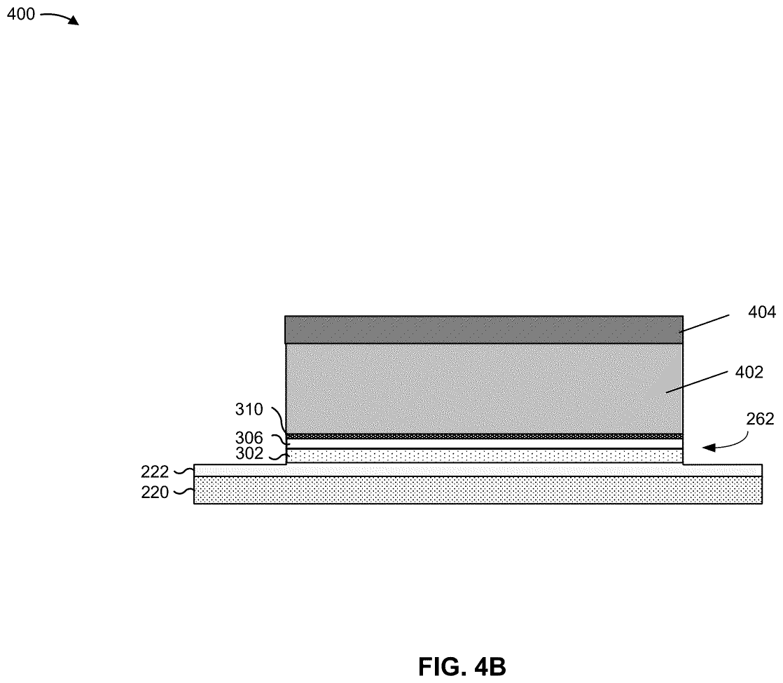

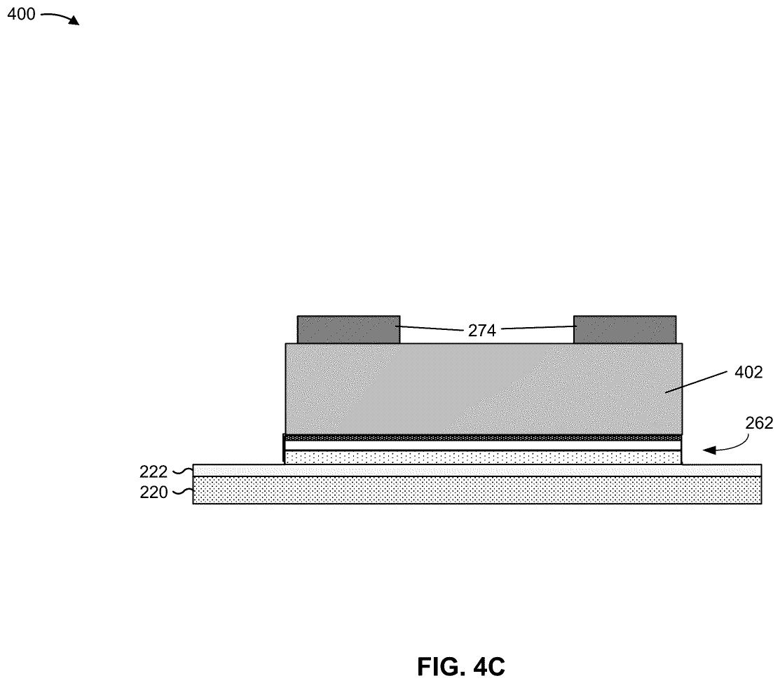

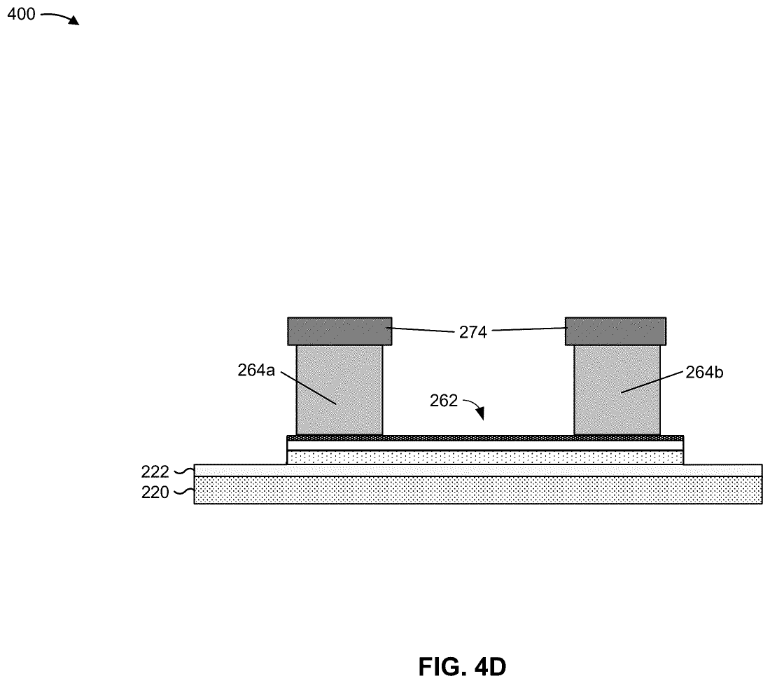

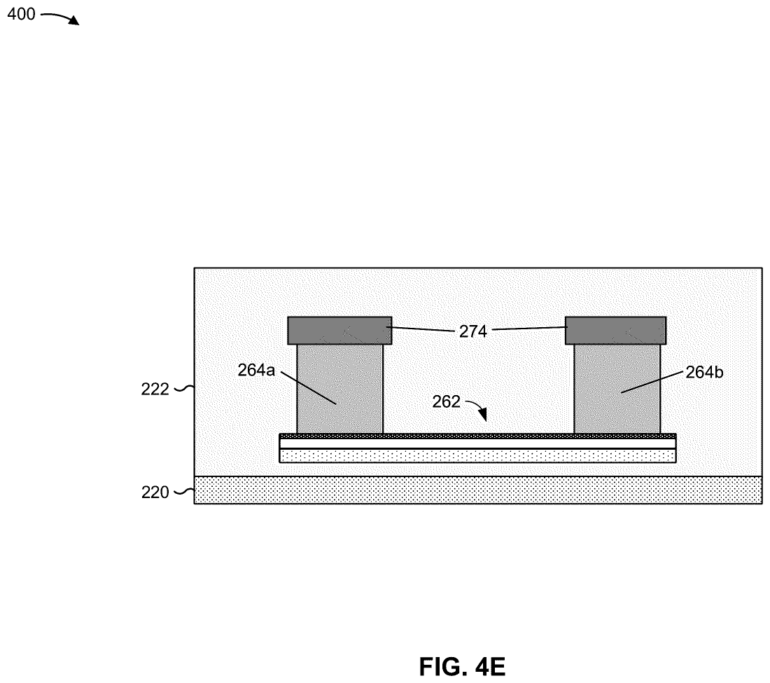

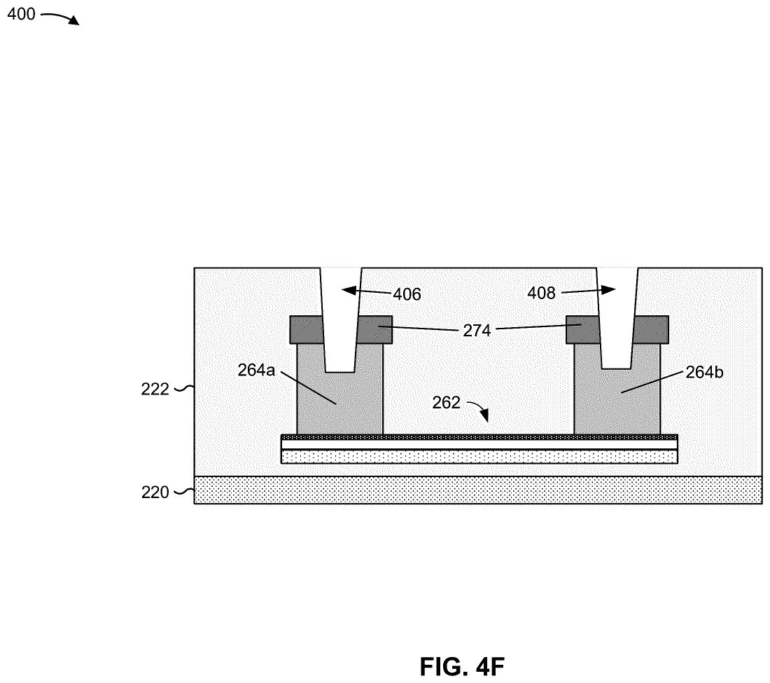

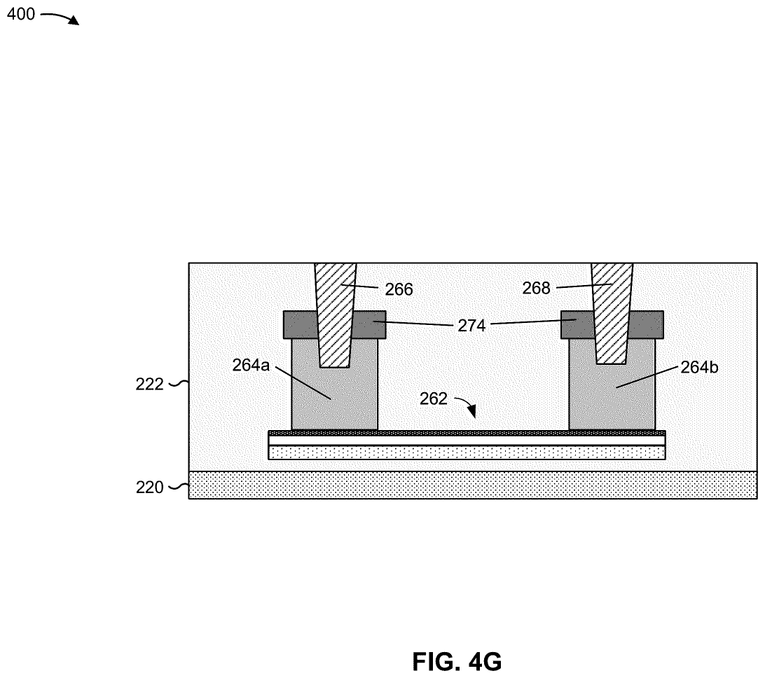

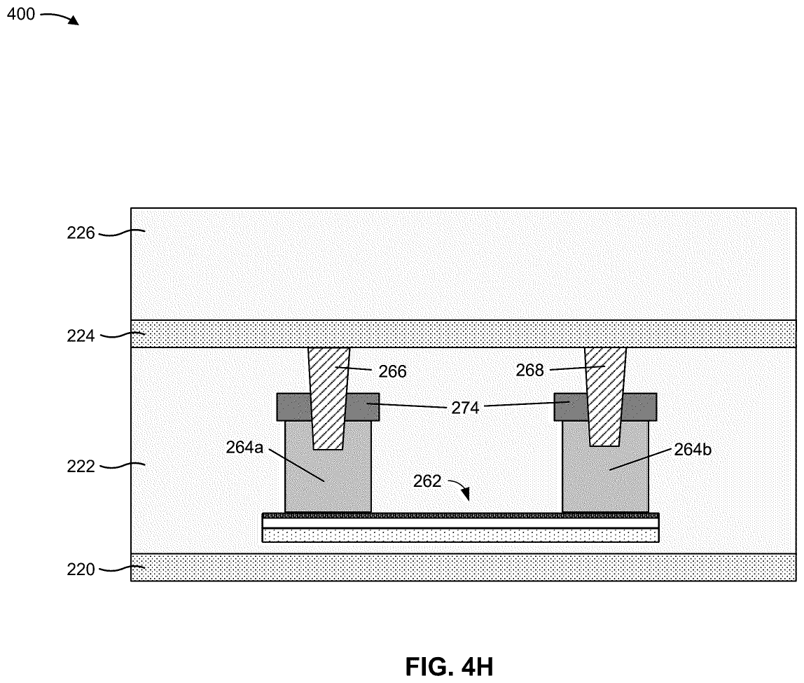

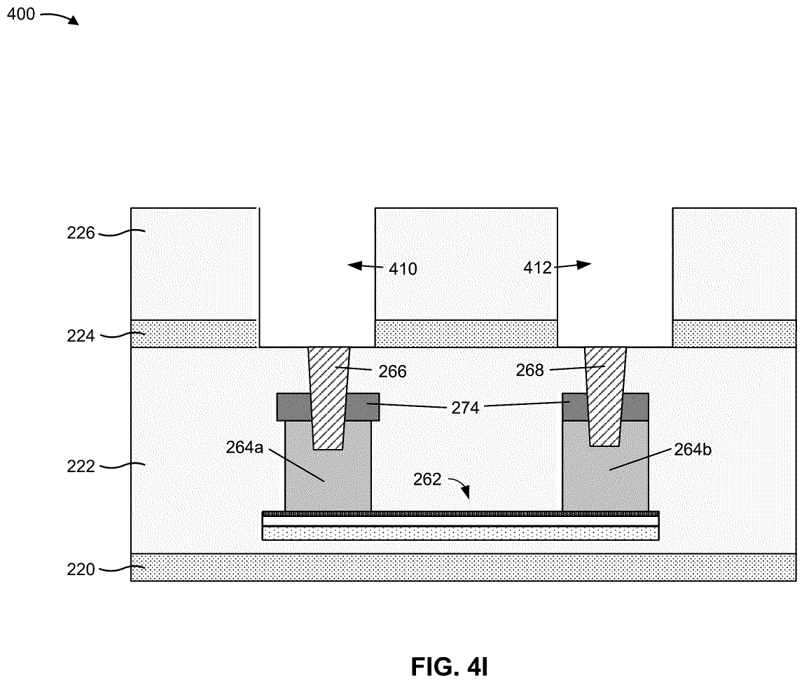

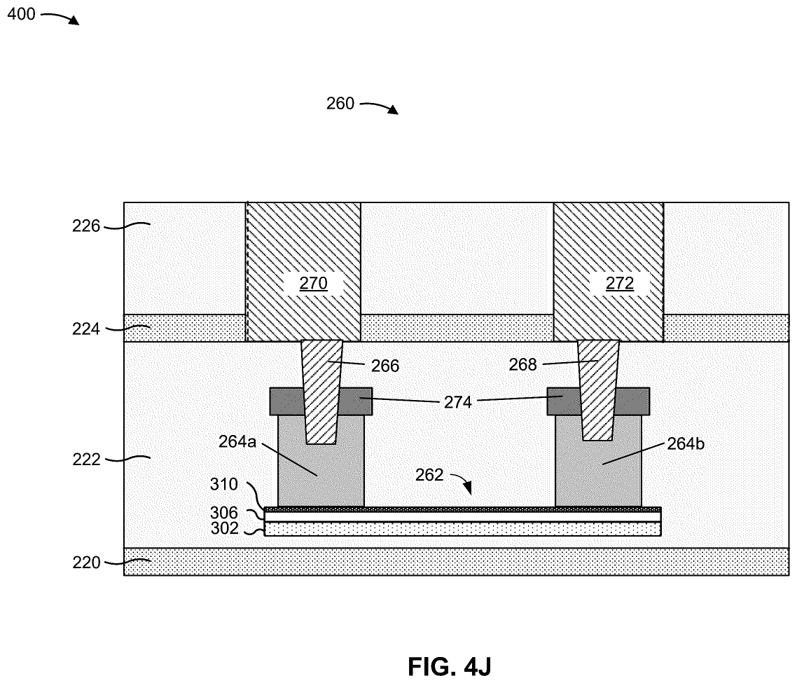

The semiconductor resistor structure 260 includes a multi-layer film structure 262. The multi-layer film structure 262 includes one or more materials configured to provide electrical resistance. As described in greater detail in connection with FIGS. 3A-3C and 4A-4J, the multi-layer film structure 262 includes a capping layer over two resistive layers, where each of the resistive layers includes a different concentration (e.g., atomic ratio) of silicon (Si). The silicon capping layer prevents oxidation within the multi-layer film structure 262 to improve a resistance uniformity (RsU) within the semiconductor resistor structure 260. Additionally, or alternatively, the two resistive layers having the different concentrations of silicon are useable to tune a thermal coefficient of resistance (TCR) and/or a mean resistance (Rs) of the semiconductor resistor structure 260.

The semiconductor resistor structure 260 includes contact structures 264a and 264b over and/or on the multi-layer film structure 262. The contact structures 264a and 264b are electrically connected with the multi-layer film structure 262, where the multi-layer film structure 262 is below the contact structures 264a and 264b. Furthermore, the contact structures 264a and 264b provide an input to, and an output from, the multi-layer film structure 262. Thus, the contact structures 264a and 264b function as the terminals of the semiconductor resistor structure 260. The contact structures 264a and 264b may each include one or more electrically conductive materials, such as titanium nitride (TiN), a ceramic material, a metal material, a metal alloy, and/or another electrically conductive material, among other examples. The contact structures 264a and 264b may be spaced apart by the dielectric layer 222 such that the contact structures 264a and 264b are electrically isolated to reduce the likelihood of electrical shorting between the contact structures 264a and 264b. In some implementations, a thickness of the contact structures 264a and 264b is included in a range of approximately 650 angstroms to approximately 850 angstroms. However, other values for the range are within the scope of the present disclosure.

The contact structure 264a may be physically coupled and/or electrically coupled with a row of vertical interconnect access structures (vias) 266 and/or another type of interconnect structure. Further, and as shown in FIG. 2, the row of vias 266 may be above a length-wise edge of the multi-layer film structure 262.

The contact structure 264b may be physically coupled and/or electrically coupled with a row of vias 268 and/or another type of interconnect structure. In some implementations, the contact structure 264b corresponds to a bus structure. Further, and as shown in FIG. 2, the row of vias 268 may be above an opposite length-wise edge of the multi-layer film structure 262.

The row of vias 266 may be physically coupled and/or electrically coupled with a conductive bus structure 270 and/or another type of metallization layer. The row of vias 268 may be physically coupled and/or electrically coupled with a conductive bus structure 272 and/or another type of metallization layer. The rows of vias 266 and 268, and/or the conductive bus structures 270 and 272, may include materials similar to those included in one or more of the structures 238-254. The rows of vias 266 and 268 may be included in the dielectric layer 222 and may respectively extend into a portion of the contact structures 264a and 264b. The conductive bus structures 270 and 272 may be included in the dielectric layer 226 and may be extend through the ESL 224. In some implementations, the conductive bus structures 270 and 272 are top metal layers in the semiconductor device 200.

Isolation layers 274 may be included over and/or on the contact structures 264a and 264b. The rows of vias 266 and 268 may extend through the isolation layers 274. The isolation layers 274 may include a silicon nitride (SiₓN_{y}), a silicon oxynitride (SiON), a high dielectric constant (high-K) dielectric material, and/or another suitable dielectric material that may provide electrical isolation for top surfaces of the contact structures 264a and 264b. The isolation layers 274 may also be used as a hard mask layer for patterning the contact structures 264a and 264b during fabrication/formation of the semiconductor resistor structure 260. In some implementations, a thickness of the isolation layers 274 may be included in a range of approximately 300 angstroms to approximately 400 angstroms. However, other values for the range are within the scope of the present disclosure.

As indicated above, FIG. 2 is provided as an example. Other examples may differ from what is described with regard to FIG. 2.

FIGS. 3A-3C are diagrams of an example implementation 300 related to forming a multi-layer film structure (e.g., the multi-layer film structure 262) described herein. The implementation 300 may be a series of operations performed by one or more of the semiconductor processing tools 102-116 described in connection with FIG. 1.

As shown in FIG. 3A, the ESL 220 and the dielectric layer 222 are formed. The deposition tool 102 may be used to deposit the ESL 220 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the ESL 220 after the ESL 220 is deposited.

Further, and as shown in FIG. 3A, the deposition tool 102 may be used to deposit the dielectric layer 222 over and/or on the ESL 220 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the dielectric layer 222 after the dielectric layer 222 is deposited.

Further, and as shown in FIG. 3A, a lower resistive layer 302 is formed over and/or on the dielectric layer 222. In some implementations, and among other examples, a respective silicon chromium composition of the lower resistive layer 302 includes a poly crystalline silicon chromium compound (SiCr) and/or a chromium silicate compound (Si₂Cr).

The deposition tool 102 may be used to deposit the lower resistive layer 302 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the lower resistive layer 302 after the lower resistive layer 302 is deposited.

In some implementations, the ion implantation tool 116 may be used to implant ions 304 (e.g., an oxygen dopant or a nitrogen dopant) in an ion implantation operation as described in connection with FIG. 1, and/or another suitable ion implantation operation. The ion implantation operation may change a magnitude and/or a uniformity of an electrical resistance of the lower resistive layer 302.

In some implementations, a thickness D1 of the lower resistive layer 302 is included in a range of approximately 40 angstroms to approximately 80 angstroms. Selecting thickness of at least 40 angstroms may ensure that the lower resistive layer 302 dissipates heat uniformly and that a thermal coefficient of resistance of a resistor structure including the lower resistive layer 302 (e.g., the semiconductor resistor structure 260) satisfies a lower threshold (e.g., an electrical resistance of the semiconductor resistor structure 260 will be more stable and less susceptible to changes with temperature variations, and will be less likely to be increased above or decreased below thresholds associated with a desired electrical resistance for an operating temperature range of the semiconductor device 200 including semiconductor resistor structure 260). A lesser thickness may not ensure that the lower resistive layer 302 can dissipate the heat uniformly and cause “hot spots” that skew a performance of the semiconductor resistor structure 260. Selecting a thickness of no more than approximately 80 angstroms ensures that the thermal coefficient of resistance of the resistor structure satisfies an upper threshold (e.g., an electrical resistance of the semiconductor resistor structure 260 will be less likely to be increased above or decreased below thresholds associated with a desired electrical resistance for the operating temperature range of the semiconductor device 200 including the semiconductor resistor structure 260.) A greater thickness may not ensure that the thermal coefficient of resistance satisfies the upper threshold (e.g., an electrical resistance of the semiconductor resistor structure 260 will be less stable and more susceptible to changes with temperature variations, and the electrical resistance of the semiconductor resistor structure 260 will be more likely to be increased above or decreased below thresholds associated with the desired electrical resistance for an operating temperature range of the semiconductor device 200 including semiconductor resistor structure 260). However, other values and ranges for the thickness D1 are within the scope of the present disclosure.

As shown in FIG. 3B, an upper resistive layer 306 is formed over and/or on the lower resistive layer 302. In some implementations, and among other examples, a respective silicon composition of the upper resistive layer 306 includes a poly crystalline silicon chromium compound (SiCr) and/or a chromium silicate compound (Si₂Cr).

The deposition tool 102 may be used to deposit the upper resistive layer 306 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the upper resistive layer 306 after the upper resistive layer 306 is deposited.

In some implementations, the ion implantation tool 116 may be used to implant ions 308 (e.g., an oxygen dopant or a nitrogen dopant) in an ion implantation operation as described in connection with FIG. 1, and/or another suitable ion implantation operation. The ion implantation operation may change a magnitude and/or a uniformity of an electrical resistance of the upper resistive layer 306.

In some implementations, a thickness D2 of the upper resistive layer 306 is included in a range of approximately 20 angstroms to approximately 60 angstroms. Selecting thickness of at least 20 angstroms may ensure that the upper resistive layer 306 dissipates heat uniformly and that a thermal coefficient of resistance of a resistor structure including the upper resistive layer 306 (e.g., the semiconductor resistor structure 260) satisfies a lower threshold (e.g., an electrical resistance of the semiconductor resistor structure 260 will be more stable and less susceptible to changes with temperature variations, and will be less likely to be increased above or decreased below thresholds associated with a desired electrical resistance for an operating temperature range of the semiconductor device including the semiconductor resistor structure 260). A lesser thickness may not ensure that the upper resistive layer 306 can dissipate heat uniformly and cause “hot spots” that skew a performance of the resistor structure. Selecting a thickness of no more than approximately 60 angstroms ensures that the thermal coefficient of resistance of the resistor structure satisfies an upper threshold (e.g., an electrical resistance of the semiconductor resistor structure 260 will be less likely to be increased above or decreased below thresholds associated with a desired electrical resistance for the operating temperature range of the semiconductor device 200 including the semiconductor resistor structure 260.) A greater thickness may not ensure that the thermal coefficient of resistance satisfies the upper threshold (e.g., an electrical resistance of the semiconductor resistor structure 260 will be less stable and more susceptible to changes with temperature variations, and the electrical resistance of the semiconductor resistor structure 260 will be more likely to be increased above or decreased below thresholds associated with the desired electrical resistance for the operating temperature range of the semiconductor device 200 including the semiconductor resistor structure 260. However, other values and ranges for the thickness D2 are within the scope of the present disclosure.

As shown in FIG. 3C, a capping layer 310 is formed on and/or over the upper resistive layer 306. Among other examples, the capping layer 310 may include a silicon material or an aluminum material.

The deposition tool 102 may be used to deposit the capping layer 310 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the capping layer 310 after the capping layer 310 is deposited.

In some implementations, a thickness D3 of the capping layer 310 is included in a range of approximately 15 angstroms to approximately 25 angstroms. Selecting a thickness of at least 15 angstroms ensures that the capping layer 310 is thick enough to prevent oxidation of the upper resistive layer 306 and/or the lower resistive layer 302. Such oxidation may increase a magnitude and/or a variation of an electrical resistance and/or a thermal coefficient of resistance of a resistor structure including the capping layer 310 (e.g., the semiconductor resistor structure 260). A lesser thickness may not prevent such an oxidation. Selecting a thickness of no more than approximately 25 angstroms ensures that the capping layer 310 is substantially oxidized to improve a stability of the electrical resistance and/or the thermal coefficient of resistance properties of the resistor structure. A greater thickness may not ensure that the capping layer 310 is sufficiently oxidized. However, other values and ranges for the thickness D3 are within the scope of the present disclosure.

The lower resistive layer 302 and the upper resistive layer 306 include a difference in concentrations (e.g., a difference in atomic ratio) of silicon, where a concentration of silicon in the lower resistive layer 302 is lesser relative to a concentration of silicon in the upper resistive layer 306.

As an example, the upper resistive layer 306 may include a first concentration of silicon (e.g., a first atomic ratio of silicon corresponding to a first concentration of silicon) that is greater than approximately 66%, and the lower resistive layer 302 may include a second concentration of silicon (e.g., a second atomic ratio of silicon corresponding to a second concentration of silicon) that is less than approximately 66%. Selecting a mix of concentrations in which first concentration of silicon is greater than approximately 66% in combination with the second concentration of silicon that is less than approximately 66% ensures that a uniformity of an electrical resistance (e.g., an RsU %) across a multi-layer film structure (e.g., the multi-layer film structure 262) including the upper resistive layer 306 and the lower resistive layer 302 satisfies a threshold (e.g., the electrical resistance may vary by less than 3%). A first concentration of silicon that is lesser than approximately 66% in combination a second concentration of silicon that is greater than approximately 66% may fail to satisfy the threshold (e.g., the electrical resistance may vary by more than 3%). However, other values and ranges for first concentration and the second concentration are within the scope of the present disclosure.

As indicated above, FIGS. 3A-3C are provided as an example. Other examples may differ from what is described with regard to FIGS. 3A-3C.

As described in connection with FIGS. 2, 3A, 3B, 3C, and elsewhere herein, a resistor structure (e.g., the semiconductor resistor structure 260) includes a first contact structure (e.g., the contact structure 264a). The resistor structure includes a second contact structure (e.g., the contact structure 264b) adjacent to the first contact structure. The resistor structure includes a multi-layer film structure (e.g., the multi-layer film structure 262) that connects the first contact structure and the second contact structure and that includes a capping layer (e.g., the capping layer 310) and an upper resistive layer (e.g., the upper resistive layer 306) below the capping layer, where the upper resistive layer includes a first concentration of silicon. The multi-layer film structure includes a lower resistive layer (e.g., the lower resistive layer 302) below the upper resistive layer, where the lower resistive layer includes a second concentration of silicon that is lesser relative to the first concentration of silicon.

Additionally, or alternatively, a semiconductor device (e.g., the semiconductor device 200) includes a plurality of etch stop layers (e.g., the ESLs 212, 216, 220, and 224) interspersed with the plurality of dielectric layers (e.g., the dielectric layers 214, 218, 222, and 226). The semiconductor device includes a plurality of interconnects (e.g., the interconnects 238 and 248) and conductive structures (e.g., the conductive structures 244 and 252) connected in a vertical arrangement that passes through the plurality of dielectric layers and the plurality of etch stop layers. The semiconductor device includes a resistor structure (e.g., the semiconductor resistor structure 260) adjacent to the plurality of interconnects and conductive structures, where the resistor structure includes contact structures (e.g., the contact structures 264a and 264b) that are adjacent to one another and a multi-layer film structure (e.g., the multi-layer film structure 262) connecting the contact structures below the contact structures.

In this way, a performance of the resistor structure including the multi-layer film structure increases (e.g., a uniformity of an electrical resistance increases) to satisfy a performance threshold. Additionally, or alternatively and based on achieving the increased yield to the performance threshold, an amount of resources (e.g., labor, raw materials, etch tools, and/or computing resources) required to fabricate a volume of a semiconductor device is decreased.

Further, and although the multi-layer film structure 262 described in connection with FIGS. 2, 3A, 3B, and 3C includes three layers of materials (e.g., a tri-layer film structure), alternate implementations of the multi-layer film structure 262 may include two layers of materials, four layers of materials, and/or other quantities of layers of materials.

FIGS. 4A-4J are diagrams of an example implementation 400 related to forming a semiconductor device including a multi-layer film structure described herein. The example implementation 400 may be performed by one or more of the semiconductor processing tools 102-112. In some implementations, one or more of the operations described in connection with the example implementation 400 may be performed by another semiconductor processing tool. In some implementations, one or more of the operations described in connection with the example implementation 400 may be performed after formation of one or more other structures or layers of the semiconductor device 200.

Turning to FIG. 4A, the operations described in connection with the example implementation 400 may be performed in a BEOL region of the semiconductor device 200. For example, a conductive layer 402 may be formed over and/or on the capping layer 310 (e.g., a top layer of a layer stack used to form the multi-layer film structure 262). Additionally, or alternatively, a hard mask layer 404 may be formed over and/or on the conductive layer 402.

The deposition tool 102 may deposit the conductive layer 402 and/or the hard mask layer 404 using an epitaxy technique, a CVD technique, a PVD technique, an ALD technique, another deposition technique described above in connection with FIG. 1, and/or a deposition technique other than as described above in connection with FIG. 1. The deposition tool 102 and/or the plating tool 112 may deposit the conductive layer 402 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the conductive layer 402 and/or the hard mask layer 404.

In some implementations, the conductive layer 402 includes a layer of a titanium nitride material (TiN) that is approximately 750 angstroms thick. Additionally, or alternatively and in some implementations, the hard masking layer 404 includes a silicon oxynitride material (SiON) that is approximately 350 angstroms thick. However, other combinations and/or thicknesses of materials for the conductive layer 402 and the hard mask layer 404 are within the scope of the present disclosure.

As shown in FIG. 4B, portions of the hard mask layer 404, the conductive layer 402, the capping layer 310, the upper resistive layer 306, and/or the lower resistive layer 302 may be removed to form the multi-layer film structure 262. In some implementations, a pattern in a photoresist layer is used to remove portions of the hard mask layer 404, the conductive layer 402, the capping layer 310, the upper resistive layer 306, and/or the lower resistive layer 302 to form the multi-layer film structure 262. In these implementations, the deposition tool 102 forms the photoresist layer over the hard mask layer 404. The exposure tool 104 exposes the photoresist layer to a radiation source to pattern the photoresist layer. The developer tool 106 develops and removes portions of the photoresist layer to expose the pattern. The etch tool 108 etches through the hard mask layer 404, through the conductive layer 402, through the capping layer 310, through the upper resistive layer 306, and through the lower resistive layer 302 to form the multi-layer film structure 262. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 4C, portions of the hard mask layer 404 may be removed. Remaining portions of the hard mask layer 404 correspond to the isolation layers 274 of the semiconductor resistor structure 260. In some implementations, a pattern in a photoresist layer is used to remove portions of the hard mask layer 404 to form the isolation layers 274. In these implementations, the deposition tool 102 forms the photoresist layer over the hard mask layer 404. The exposure tool 104 exposes the photoresist layer to a radiation source to pattern the photoresist layer. The developer tool 106 develops and removes portions of the photoresist layer to expose the pattern. The etch tool 108 etches through the hard mask layer 404 to form the isolation layers 274. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 4D, portions of the conductive layer 402 are removed. Remaining portions of the conductive layer 402 correspond to the contact structures 264a and 264b. The etch tool 108 may etch the conductive layer 402 to remove the portions of the conductive layer 402. The etch tool 108 may etch the conductive layer 402 based on a pattern in the hard mask layer 404 that was formed in the operation to remove the portions of the hard mask layer 404 to form the isolation layers 274. In other words, the isolation layers 274 function as an etch pattern to etch the conductive layer 402 to form the contact structures 264a and 264b. In some implementations, the etch operation includes a plasma etch technique, a wet chemical etch technique, and/or another type of etch technique. Further, and in some implementations and as shown in FIG. 4D, the etch operation may cause portions of the isolation layers 274 to overhang the contact structures 264a and 264b.

As shown in FIG. 4E, an additional portion of the dielectric layer 222 may be formed over, on, and/or around the semiconductor resistor structure 260. The deposition tool 102 may deposit the additional portion of the dielectric layer 222 using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may perform a CMP operation to planarize the dielectric layer 222 after the additional portion of the dielectric layer 222 is deposited.

As shown in FIG. 4F, recesses 406 and 408 may be respectively formed in the dielectric layer 222, through the isolation layers 274, and into portions of the contact structures 264a and 264b. In these implementations, the deposition tool 102 forms the photoresist layer over the dielectric layer 222. The exposure tool 104 exposes the photoresist layer to a radiation source to pattern the photoresist layer. The developer tool 106 develops and removes portions of the photoresist layer to expose the pattern. The etch tool 108 etches through the dielectric layer 222, through the isolation layers 274, and into the portions of the contact structures 264a and 264b to respectively form the recesses 406 and 408. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 4G, the recesses 406 and 408 may be filled with one or more conductive materials to respectively form the rows of vias 266 and 268 in the recesses 406 and 408. The deposition tool 102 and/or the plating tool 112 may deposit the rows of vias 266 and 268 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the rows of vias 266 and/or the rows of vias 268.

As shown in FIG. 4H, additional layers of the BEOL region may be formed over the semiconductor resistor structure 260. For example, the ESL 224 may be formed over the semiconductor resistor structure 260 and over and/or on the dielectric layer 222. As another example, the dielectric layer 226 may be formed over and/or on the ESL 224. The deposition tool 102 may deposit the ESL 224 and/or the dielectric layer 226 using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may perform a CMP operation to planarize the ESL 224 and/or the dielectric layer 226 after the ESL 224 and/or the dielectric layer 226 is deposited.

As shown in FIG. 4I, recesses 410 and 412 may be respectively formed through the dielectric layer 226 and through the ESL 224 to expose top surfaces of the rows of vias 266 and 268, respectively. In some implementations, an edge of the recess 410 (e.g., an inner edge) is biased towards the row of vias 266. In some implementations, an edge of the recess 412 (e.g., an inner edge) is biased towards the row of vias 268.

In these implementations, the deposition tool 102 forms the photoresist layer over the dielectric layer 226. The exposure tool 104 exposes the photoresist layer to a radiation source to pattern the photoresist layer. The developer tool 106 develops and removes portions of the photoresist layer to expose the pattern. The etch tool 108 etches through the dielectric layer 226 and through the ESL 224 to form the recesses 410 and 412. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 4J, the recesses 410 and 412 may be filled with one or more conductive materials to respectively form the conductive bus structures 270 and 272 in the recesses 410 and 412. The deposition tool 102 and/or the plating tool 112 may deposit the conductive bus structures 270 and 272 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the conductive bus structures 270 and 272.

As indicated above, FIGS. 4A-4J are provided as an example. Other examples may differ from what is described with regard to FIGS. 4A-4J.

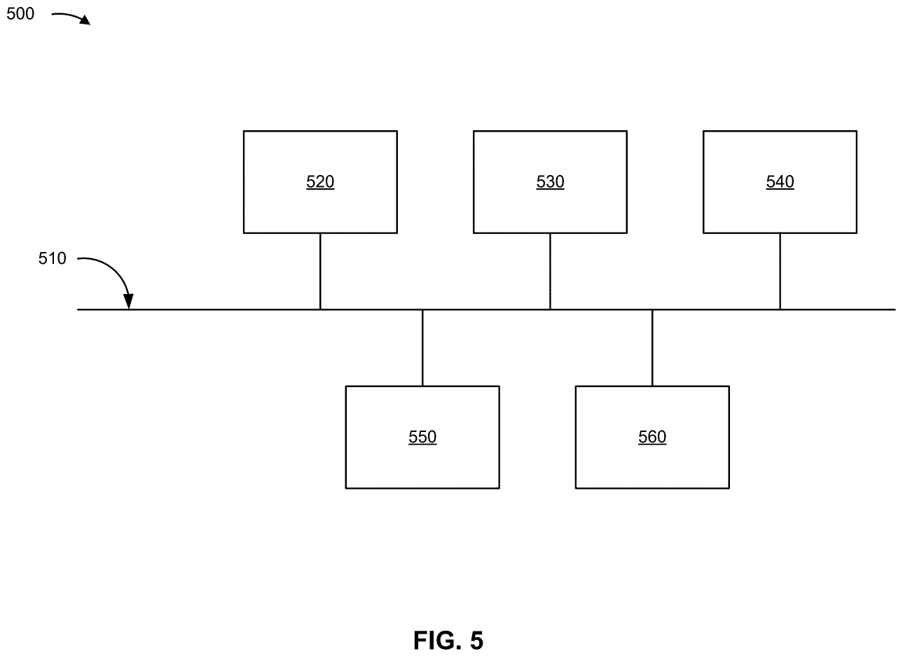

FIG. 5 is a diagram of example components of a device 500 described herein. In some implementations, one or more of the semiconductor processing tools 102-116 and/or the wafer/die transport tool 118 may include one or more devices may include one or more devices 500 and/or one or more components of the device 500. As shown in FIG. 5, the device 500 may include a bus 510, a processor 520, a memory 530, an input component 540, an output component 550, and/or a communication component 560.

The bus 510 may include one or more components that enable wired and/or wireless communication among the components of the device 500. The bus 510 may couple together two or more components of FIG. 5, such as via operative coupling, communicative coupling, electronic coupling, and/or electric coupling. For example, the bus 510 may include an electrical connection (e.g., a wire, a trace, and/or a lead) and/or a wireless bus. The processor 520 may include a central processing unit, a graphics processing unit, a microprocessor, a controller, a microcontroller, a digital signal processor, a field-programmable gate array, an application-specific integrated circuit, and/or another type of processing component. The processor 520 may be implemented in hardware, firmware, or a combination of hardware and software. In some implementations, the processor 520 may include one or more processors capable of being programmed to perform one or more operations or processes described elsewhere herein.

The memory 530 may include volatile and/or nonvolatile memory. For example, the memory 530 may include random access memory (RAM), read only memory (ROM), a hard disk drive, and/or another type of memory (e.g., a flash memory, a magnetic memory, and/or an optical memory). The memory 530 may include internal memory (e.g., RAM, ROM, or a hard disk drive) and/or removable memory (e.g., removable via a universal serial bus connection). The memory 530 may be a non-transitory computer-readable medium. The memory 530 may store information, one or more instructions, and/or software (e.g., one or more software applications) related to the operation of the device 500. In some implementations, the memory 530 may include one or more memories that are coupled (e.g., communicatively coupled) to one or more processors (e.g., processor 520), such as via the bus 510. Communicative coupling between a processor 520 and a memory 530 may enable the processor 520 to read and/or process information stored in the memory 530 and/or to store information in the memory 530.

The input component 540 may enable the device 500 to receive input, such as user input and/or sensed input. For example, the input component 540 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 550 may enable the device 500 to provide output, such as via a display, a speaker, and/or a light-emitting diode. The communication component 560 may enable the device 500 to communicate with other devices via a wired connection and/or a wireless connection. For example, the communication component 560 may include a receiver, a transmitter, a transceiver, a modem, a network interface card, and/or an antenna.

The device 500 may perform one or more operations or processes described herein. For example, a non-transitory computer-readable medium (e.g., memory 530) may store a set of instructions (e.g., one or more instructions or code) for execution by the processor 520. The processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry may be used instead of or in combination with the instructions to perform one or more operations or processes described herein. Additionally, or alternatively, the processor 520 may be configured to perform one or more operations or processes described herein. Thus, implementations described herein are not limited to any specific combination of hardware circuitry and software.

The number and arrangement of components shown in FIG. 5 are provided as an example. The device 500 may include additional components, fewer components, different components, or differently arranged components than those shown in FIG. 5. Additionally, or alternatively, a set of components (e.g., one or more components) of the device 500 may perform one or more functions described as being performed by another set of components of the device 500.

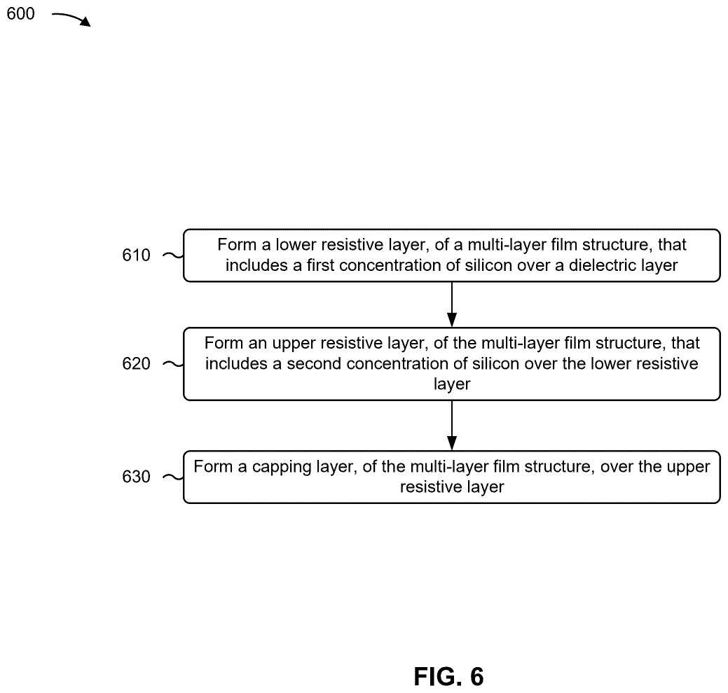

FIG. 6 is a flowchart of an example process 600 associated with forming a multi-layer film structure included as part of a resistor structure described herein (e.g., the multi-layer film structure 262 included as part of the semiconductor resistor structure 260). In some implementations, one or more process blocks of FIG. 6 are performed using one or more semiconductor processing tools (e.g., one or more of the semiconductor processing tools 102-116). Additionally, or alternatively, one or more process blocks of FIG. 6 may be performed using one or more components of device 500, such as processor 520, memory 530, input component 540, output component 550, and/or communication component 560.

As shown in FIG. 6, process 600 may include forming a lower resistive layer, of a multi-layer film structure, that includes a first concentration of silicon over a dielectric layer (block 610). For example, one or more of the semiconductor processing tools 102-116 may be used to form a lower resistive layer (e.g., the lower resistive layer 302), of a multi-layer film structure (e.g., the multi-layer film structure 262), that includes a first concentration of silicon over a dielectric layer (e.g., the dielectric layer 222), as described herein.

As further shown in FIG. 6, process 600 may include forming an upper resistive layer, of the multi-layer film structure, that includes a second concentration of silicon over the lower resistive layer (block 620). For example, one or more of the semiconductor processing tools 102-116 may be used to form an upper resistive layer (e.g., the upper resistive layer 306), of the multi-layer film structure, that includes a second concentration of silicon over the lower resistive layer, as described herein. In some implementations, the second concentration of silicon is different than the first concentration of silicon.

As further shown in FIG. 6, process 600 may include forming a capping layer, of the multi-layer film structure, over the upper resistive layer (block 630). For example, one or more of the semiconductor processing tools 102-116 may be used to form a capping layer (e.g., the capping layer 310), of the multi-layer film structure, over the upper resistive layer, as described herein.

Process 600 may include additional implementations, such as any single implementation or any combination of implementations described below and/or in connection with one or more other processes described elsewhere herein.

In a first implementation, forming the lower resistive layer includes forming the lower resistive layer using a physical vapor deposition process.

In a second implementation, alone or in combination with the first implementation, forming the lower resistive layer includes performing an ion implantation operation to dope the lower resistive layer with oxygen or nitrogen.

In a third implementation, alone or in combination with one or more of the first and second implementations, forming the upper resistive layer includes forming the upper resistive layer using a physical vapor deposition process.

In a fourth implementation, alone or in combination with one or more of the first through third implementations, forming the upper resistive layer includes performing an ion implantation operation to dope the upper resistive layer with oxygen or nitrogen.

In a fifth implementation, alone or in combination with one or more of the first through fourth implementations, process 600 includes forming contacts (e.g., the contact structures 264a and 264b) of a resistor structure (e.g., the resistor structure 260) on the capping layer.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

Some implementations described herein provide a semiconductor device including a resistor structure. The resistor structure (e.g., a thin film resistor structure) includes a multi-layer film structure connecting contact structures of the resistor structure below the contact structures. The multi-layer film structure includes a capping layer, an upper resistive layer having a first concentration of silicon, and a lower resistive layer having a second concentration of silicon that is lesser relative to the first concentration. The multi-layer film structure may be subject to a lesser risk of oxidation relative to a single layer film structure that does not include the capping layer. Additionally, or alternatively, the combination of the upper and lower resistive layers (e.g., including the first and second concentrations of silicon) may allow for tuning of a mean resistive property and/or a temperature coefficient across the multi-layer film structure to reduce a variation in a performance of the semiconductor device relative to another semiconductor device including another resistor structure using a single layer film structure.

In this way, a performance of the resistor structure including the multi-layer film structure is increased to satisfy a performance threshold. Additionally, or alternatively and based on a population of semiconductor devices including the resistor structure achieving an increased testing yield to the performance threshold, an amount of resources (e.g., labor, raw materials, semiconductor processing tools, and/or computing resources) required to fabricate the population of semiconductor devices is decreased.

As described in greater detail above, some implementations described herein provide a resistor structure. The resistor structure includes a first contact structure. The resistor structure includes a second contact structure adjacent to the first contact structure. The resistor structure includes a multi-layer film structure that connects the first contact structure and the second contact structure and that includes a capping layer and an upper resistive layer below the capping layer, where the upper resistive layer includes a first concentration of silicon. The multi-layer film structure includes a lower resistive layer below the upper resistive layer, where the lower resistive layer includes a second concentration of silicon that is lesser relative to the first concentration of silicon.

As described in greater detail above, some implementations described herein provide a semiconductor device. The semiconductor device includes a plurality of dielectric layers in a stacked arrangement. The semiconductor device includes a plurality of etch stop layers interspersed with the plurality of dielectric layers. The semiconductor device includes a plurality of interconnects and conductive structures connected in a vertical arrangement that passes through the plurality of dielectric layers and the plurality of etch stop layers. The semiconductor device includes a resistor structure adjacent to the plurality of interconnects and conductive structures, where the resistor structure includes contact structures that are adjacent to one another and a multi-layer film structure connecting the contact structures below the contact structures.

As described in greater detail above, some implementations described herein provide a method. The method includes forming a lower resistive layer, of a multi-layer film structure, that includes a first concentration of silicon over a dielectric layer. The method includes forming an upper resistive layer, of the multi-layer film structure, that includes a second concentration of silicon over the lower resistive layer, where the second concentration of silicon is different than the first concentration of silicon. The method includes forming a capping layer, of the multi-layer film structure, over the upper resistive layer.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A resistor structure, comprising:
a first contact structure;
a second contact structure adjacent to the first contact structure; and
a multi-layer film structure that connects the first contact structure and the second contact structure and that comprises:
a capping layer;
an upper resistive layer below the capping layer,
wherein the upper resistive layer includes a first concentration of silicon; and
a lower resistive layer below the upper resistive layer,
wherein the lower resistive layer includes a second concentration of silicon that is lesser relative to the first concentration of silicon.

2. The resistor structure of claim 1, wherein the upper resistive layer comprises a first silicon chromium composition with the first concentration of silicon, and
wherein the lower resistive layer comprises a second silicon chromium composition with the second concentration of silicon.

3. The resistor structure of claim 2, wherein the first silicon chromium composition and the second silicon chromium composition each comprises:
a respective silicon chromium composition including a poly crystalline silicon chromium compound and a chromium silicate compound.

4. The resistor structure of claim 1, wherein a first atomic ratio corresponding to the first concentration of silicon is greater than approximately 66%, and
wherein a second atomic ratio corresponding to the second concentration of silicon is lesser less than approximately 66%.

5. The resistor structure of claim 1, wherein a thickness of the capping layer is included in a range of approximately 15 angstroms to approximately 25 angstroms.

6. The resistor structure of claim 1, wherein a thickness of the upper resistive layer is included in a range of approximately 20 angstroms to approximately 60 angstroms.

7. The resistor structure of claim 1, wherein a thickness of the lower resistive layer is included in a range of approximately 40 angstroms to approximately 80 angstroms.

8. A semiconductor device, comprising:
a plurality of dielectric layers in a stacked arrangement;
a plurality of etch stop layers interspersed with the plurality of dielectric layers;
a plurality of interconnects and conductive structures connected in a vertical arrangement that passes through the plurality of dielectric layers and the plurality of etch stop layers; and
a resistor structure adjacent to the plurality of interconnects and conductive structures, comprising:
contact structures that are adjacent to one another; and
a multi-layer film structure connecting the contact structures below the contact structures.

9. The semiconductor device of claim 8, wherein the multi-layer film structure comprises:
an upper resistive layer comprising a first concentration of silicon, and
a lower resistive layer comprising a second concentration of silicon,
wherein a difference between the first concentration of silicon and the second concentration of silicon increases a uniformity of an electrical resistance of the multi-layer film structure relative to a single layer film structure.

10. The semiconductor device of claim 9, wherein the upper resistive layer comprises:
an oxygen dopant, or
a nitrogen dopant.

11. The semiconductor device of claim 9, wherein the lower resistive layer comprises:
an oxygen dopant, or
a nitrogen dopant.

12. The semiconductor device of claim 9, wherein the multi-layer film structure is a tri-layer film structure that further comprises:
a capping layer.

13. The semiconductor device of claim 12, wherein:
the upper resistive layer is on the lower resistive layer, and
the capping layer is on the upper resistive layer.

14. The semiconductor device of claim 12, wherein the capping layer comprises:
a silicon material, or
an aluminum material.

15. A method, comprising:
forming a lower resistive layer, of a multi-layer film structure, that includes a first concentration of silicon over a dielectric layer;
forming an upper resistive layer, of the multi-layer film structure, that includes a second concentration of silicon over the lower resistive layer,
wherein the second concentration of silicon is different than the first concentration of silicon; and
forming a capping layer, of the multi-layer film structure, over the upper resistive layer.

16. The method of claim 15, wherein forming the lower resistive layer includes:
forming the lower resistive layer using a physical vapor deposition process.

17. The method of claim 15, wherein forming the lower resistive layer includes:
performing an ion implantation operation to dope the lower resistive layer with oxygen or nitrogen.

18. The method of claim 15, wherein forming the upper resistive layer includes:
forming the upper resistive layer using a physical vapor deposition process.

19. The method of claim 15, wherein forming the upper resistive layer includes:
performing an ion implantation operation to dope the upper resistive layer with oxygen or nitrogen.

20. The method of claim 15, further comprising:
forming contacts of a resistor structure on the capping layer.
